(19) United States
(12) Patent Application Publication
(10) Pub. No.: US 2008/0265419 A1
(43) Pub. Date: Oct. 30, 2008

(54) SEMICONDUCTOR STRUCTURE COMPRISING AN ELECTRICALLY CONDUCTIVE FEATURE AND METHOD OF FORMING THE SAME

(76) Inventors: Kai Frohberg, Niederau (DE); Frank FEUSTEL, Dresden (DE); Carsten PETERS, Dresden (DE)

Correspondence Address: WILLIAMS, MORGAN & AMERSON, 10333 RICHMOND, SUITE 1100, HOUSTON, TX, 77042, US

(21) Appl. No.: 11/944,039

(22) Filed: Nov. 21, 2007

(30) Foreign Application Priority Data
Apr. 30, 2007 (DE) 10 2007 020 266.2

(51) Int. Cl. H01L 23/52; H01L 21/4763

(52) U.S. Cl. 257/753; 438/644; 257/E23.141; 257/E21.495

(57) ABSTRACT

A method of forming a semiconductor structure comprises providing a semiconductor substrate comprising a layer of a dielectric material. A recess is provided in the layer of dielectric material. A first glue layer and a second glue layer are formed over the recess. The first glue layer comprises titanium and the second glue layer comprises tungsten nitride. The recess is filled with a material comprising tungsten.

### BACKGROUND OF THE INVENTION

1. Field of the Invention

The subject matter disclosed herein generally relates to the fabrication of integrated circuits, and, more particularly, to the formation of electrically conductive features connecting circuit elements in integrated circuits.

2. Description of the Related Art

Integrated circuits comprise a large number of individual circuit elements, e.g., transistors, capacitors and resistors. These elements are connected by means of electrically conductive features to form complex circuits, such as memory devices, logic devices and microprocessors. The performance of integrated circuits may be improved by increasing the number of functional elements per circuit in order to increase the circuit's functionality and/or by increasing the speed of operation of the circuit elements. A reduction of feature sizes allows the formation of a greater number of circuit elements on the same area, hence increasing the functionality of the circuit, and also reducing signal propagation delays, thus making an increase of the speed of operation of circuit elements possible.

As feature sizes in integrated circuits are reduced, sophisticated techniques are required in order to electrically connect the circuit elements of the integrated circuits. If a greater number of circuit elements are formed on the same area, it may be necessary to reduce the dimensions of the electrically conductive features in order to accommodate the electrically conductive features. Additionally, electrically conductive features may be formed in a plurality of levels stacked on top of each other.

In modern integrated circuits, electrically conductive features in higher interconnect levels are frequently made of copper. If, however, copper diffuses into a silicon substrate wherein circuit elements are formed and is incorporated into the crystal lattice of the silicon substrate, deep impurity levels may be created. Such deep impurity levels may lead to a degradation of the performance of circuit elements, such as field effect transistors. In order to avoid such problems, electrical connections between circuit elements and the first level of electrically conductive lines are frequently made of tungsten.

A method of forming a semiconductor structure according to the state of the art will be described with reference to FIGS. 1a-1b. FIG. 1a shows a schematic cross-sectional view of a semiconductor structure 100 in a first stage of a manufacturing method according to the state of the art.

The semiconductor structure 100 comprises a substrate 101. The substrate 101, which may, for example, comprise silicon, comprises a field effect transistor 102. The field effect transistor 102 comprises an active region 103, a source region 108 and a drain region 109. In examples of manufacturing methods according to the state of the art wherein the field effect transistor 102 is an N-type transistor, the material of the substrate 101 may be P-doped. The source region 108 and the drain region 109 may be N-doped. Conversely, in examples of manufacturing methods according to the state of the art wherein the field effect transistor 102 is a P-type transistor, the active region 103 may be N-doped and the source region 108, as well as the drain region 109, may be P-doped. Thus, a PN transition is provided at an interface between the source region 108 and the active region 103 and at an interface between the drain region 109 and the active region 103.

The field effect transistor 102 further comprises a gate electrode 105 flanked by a sidewall spacer structure 107 and separated from the active region 103 by a gate insulation layer 106. A trench isolation structure 104 provides electrical insulation between the field effect transistor 102 and other circuit elements in the semiconductor structure 100. The field effect transistor 102 may be formed by means of methods well known to persons skilled in the art, including advanced techniques of ion implantation, deposition, photolithography, etching, oxidation and annealing.

A layer 110 of a dielectric material is deposited over the substrate 101. The layer 110 may comprise silicon dioxide, silicon nitride and/or silicon oxynitride and may be formed by means of known deposition techniques, such as chemical vapor deposition and plasma enhanced chemical vapor deposition. A thickness of the layer 110 may be greater than a height of the gate electrode 105. After the deposition of the layer 110, a known planarization process, such as chemical mechanical polishing, may be performed to obtain a planar surface of the layer 110.

Contact vias 111, 112, 113 are formed in the layer 110. To this end, a mask (not shown) covering the layer 110, with the exception of those portions wherein the contact vias 111, 112, 113 are to be formed, is formed over the semiconductor structure 100 by means of known methods of photolithography. Thereafter, a known anisotropic etching process, for example, a dry etching process, is performed to remove those portions of the layer 110 which are not covered by the mask. The anisotropy of the etching process may help obtain substantially vertical sidewalls of the contact vias 111, 112, 113.

The contact via 111 is formed over the source region 108. Thus, at the bottom of the contact via 111, a portion of the source region 108 is exposed. The contact vias 112, 113 are formed over the gate electrode 105 and the drain region 109, respectively. Hence, the gate electrode 105 is exposed at the bottom of the contact via 112 and the drain region 109 is exposed at the bottom of the contact via 113.

In some examples of manufacturing methods according to the state of the art, an etch stop layer (not shown) comprising a material which is etched at a significantly lower etch rate than the dielectric material of the layer 110 may be provided between the field effect transistor 102 and the layer 110. Thus, the etch process may be reliably stopped as soon as the vias 111, 112, 113 penetrate the layer 110 of dielectric material. After the formation of the contact vias 111, 112, 113, a second etching process may be performed in order to remove portions of the etch stop layer exposed at the bottom of the contact vias 111, 112, 113.

After the formation of the contact vias 111, 112, 113, the mask may be removed, for example, by means of a known resist strip process. Subsequently, the contact vias 111, 112, 113 are filled with tungsten. To this end, a titanium layer 114 and a titanium nitride layer 115 are deposited over the semiconductor structure 100. The layers 114, 115 may improve an adhesion between the tungsten provided in the contact vias 111, 112, 113 and the dielectric material of the layer 110.

A seed layer 116 comprising tungsten is formed over the semiconductor structure 100. The seed layer 116 may be formed by means of an atomic layer deposition process. As persons skilled in the art know, atomic layer deposition is a variant of chemical vapor deposition wherein the semiconductor structure 100 is sequentially exposed to a plurality of gaseous precursor compounds which are sequentially flown to a reactor vessel wherein the semiconductor structure 100 is provided. While a first precursor is flown to the semiconductor structure 100, a substantially monoatomic layer of the first precursor is formed over the titanium nitride layer 115. Since an adhesion between molecules of the first precursor may be weak, a deposition of more than one monoatomic layer of the first precursor can be substantially avoided by adapting the temperature of the atomic layer deposition process. Thereafter, a second precursor is flown to the semiconductor structure 100. The second precursor reacts chemically with the first precursor present on the surface of the semiconductor structure 100. In the chemical reaction, tungsten may be created.

After the formation of the seed layer 116, a layer 117 comprising tungsten may be formed over the seed layer 116. To this end, well-known deposition techniques, such as chemical vapor deposition and/or plasma enhanced chemical vapor deposition, may be employed. Subsequently, a chemical mechanical polishing process adapted to remove portions of the layers 114, 115, the seed layer 116 and the layer 117 comprising tungsten deposited outside the contact vias 111, 112, 113 may be performed.

FIG. 1b shows a schematic cross-sectional view of the semiconductor structure 100 in a later stage of the manufacturing process according to the state of the art. A second layer 121 of a dielectric material is formed over the first layer 110 of dielectric material. In some examples of manufacturing processes according to the state of the art, the second layer 121 may comprise the same material as the first dielectric layer 110. Alternatively, the second layer 121 may comprise a different material than the first dielectric layer 110, for example, a low-k material such as hydrogen silsesquioxane.

Trenches 122, 123, 124 are formed in the second layer 121 of dielectric material. This may be done by means of techniques of photolithography and etching well known to persons skilled in the art.

A diffusion barrier layer 125 is formed over the semiconductor structure 100. The diffusion barrier layer 125 may comprise tantalum and/or tantalum nitride and may be adapted to prevent a diffusion of copper which will be provided in the trenches 122, 123, 124 into other portions of the semiconductor structure 100.

Subsequently, a seed layer 127 comprising copper is formed over the semiconductor structure 100. This may be done by means of well-known methods, such as chemical vapor deposition and/or plasma enhanced chemical vapor deposition. Thereafter, a layer 126 comprising copper is formed over the seed layer 127, for example, by means of an electroplating process well known to persons skilled in the art. Finally, portions of the seed layer 127 and the layer 206 outside the trenches 122, 123, 124 are removed, for example, by means of a chemical mechanical polishing process.

A problem of the above-described manufacturing process according to the state of the art is that the titanium nitride layer 115 may comprise inhomogeneous surface properties. In the formation of the seed layer 116 and/or the formation of the layer 117 comprising tungsten, the surface inhomogeneity of the titanium nitride layer 115 may lead to nucleation issues which, in turn, may lead to a formation of voids and/or seams of the layer 117. The presence of voids and/or seams may increase the electrical resistivity of the layer 117, which may adversely affect the functionality of the semiconductor structure 100.

A further problem of the above-described manufacturing process according to the state of the art is that an insufficient step coverage of the titanium nitride layer 115 may be obtained. Hence, a thickness of the titanium nitride layer 115 at sidewalls of the contact vias 111, 112, 113 may be insufficient to insure a proper adhesion of the seed layer 116. This may also entail nucleation issues in the formation of the layer 117 comprising tungsten.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to one illustrative example, the method involves providing a semiconductor substrate comprising a layer of a dielectric material, forming a recess in the layer of dielectric material and forming a first glue layer and a second glue layer over the recess. The first glue layer comprises titanium and the second glue layer comprises tungsten nitride. The recess is filled with a material comprising tungsten.

According to another illustrative example, the method involves providing a semiconductor substrate comprising a field effect transistor, forming a layer of a dielectric material over the field effect transistor and forming a first contact via and a second contact via in the layer of dielectric material. The first contact via is provided over the source region and the second contact via is provided over the drain region of the transistor. A first glue layer comprising titanium is formed over a bottom surface of the first contact via and a bottom surface of the second contact via. A second glue layer comprising tungsten nitride is formed over the first contact via and the second contact via. The first contact via and the second contact via are filled with a material comprising tungsten.

According to yet another illustrative example, a semiconductor structure is disclosed. The device comprises a semiconductor substrate comprising a layer of a dielectric material. A recess is provided in the layer of dielectric material. A first glue layer and a second glue layer are formed over the recess. The first glue layer comprises titanium and the second glue layer comprises tungsten nitride. The recess is filled with a material comprising tungsten.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b show schematic cross-sectional views of a semiconductor structure in stages of a method of manufacturing a semiconductor structure according to the state of the art;

FIGS. 2a-2c show schematic cross-sectional views of a semiconductor structure in stages of a method of manufacturing a semiconductor structure according to one illustrative embodiment disclosed herein; and

FIG. 3 shows a schematic cross-sectional view of a portion of a semiconductor structure in a stage of a method of manufacturing a semiconductor structure according to another illustrative embodiment disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

According to one embodiment, a glue layer comprising tungsten nitride is provided in a recess wherein an electrical connection to a circuit element is to be formed from a material comprising tungsten. The recess may, in some embodiments, comprise a contact via. Advantageously, a glue layer comprising tungsten nitride having a relatively small thickness, in a range from about 1-15 nm, may be reliably formed in a contact via having a diameter in a range from about 80-200 nm and an aspect ratio of more than about 5. Hence, nucleation issues which may occur in semiconductor structures according to the state of the art, wherein a layer comprising titanium nitride is used, may be reduced. A further glue layer comprising titanium may be provided below the tungsten nitride glue layer in order to improve an adhesion between the tungsten nitride glue layer and a portion of the circuit element comprising a metal silicide such as, for example, a source region, a drain region or a gate electrode of a field effect transistor. Thus, a separation of the electrical connection from the metal silicide or even a complete removal of the electrical connection from the recess caused by mechanical forces which might, for example, occur during a chemical mechanical polishing process may be advantageously avoided. In some embodiments, the glue layer comprising titanium may comprise substantially pure titanium. In other embodiments, an alloy comprising titanium may be used.

In some embodiments, the glue layer comprising tungsten nitride may have a smaller thickness at the bottom of the contact via than at a sidewall of the contact via. To this end, a sputtering process may be performed after the formation of the glue layer comprising tungsten nitride. In the sputtering process, tungsten nitride may be sputtered away from the bottom surface of the contact via to reduce the thickness of the tungsten nitride glue layer at the bottom surface, and at least a portion of the tungsten nitride may be deposited on the sidewall of the contact via, thereby increasing the thickness of the tungsten nitride glue layer on the sidewall. Reducing the thickness of the tungsten nitride glue layer at the bottom of the contact via may help in reducing electric resistivity between the electrical connection and the circuit element contacted by the electrical connection.

In further embodiments, the glue layer comprising titanium may have a greater thickness at the bottom of the contact via than at the sidewall of the contact via. To this end, an anisotropic deposition process may be employed in the formation of the glue layer comprising titanium. In the anisotropic deposition process, a rate of material deposition on substantially horizontal surfaces, such as the bottom of the contact via, may be greater than a rate of material deposition on inclined surfaces, such as the sidewall of the contact via. Thus, a greater thickness of the glue layer comprising titanium may be obtained at the bottom of the contact via. Advantageously, this may help provide a particularly strong adhesion between the electrical connection and the circuit element contacted by the electrical connection, while simultaneously reducing an amount of space in the contact via occupied by the glue layer comprising titanium.

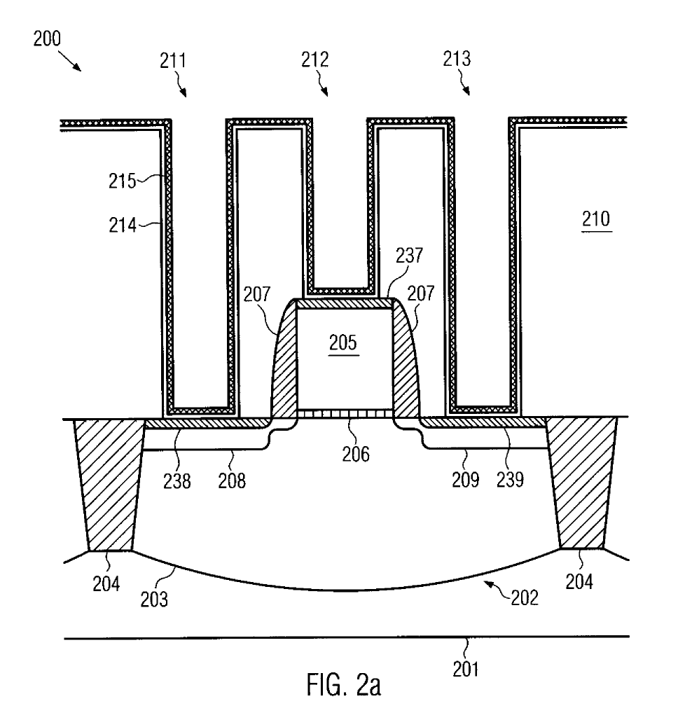

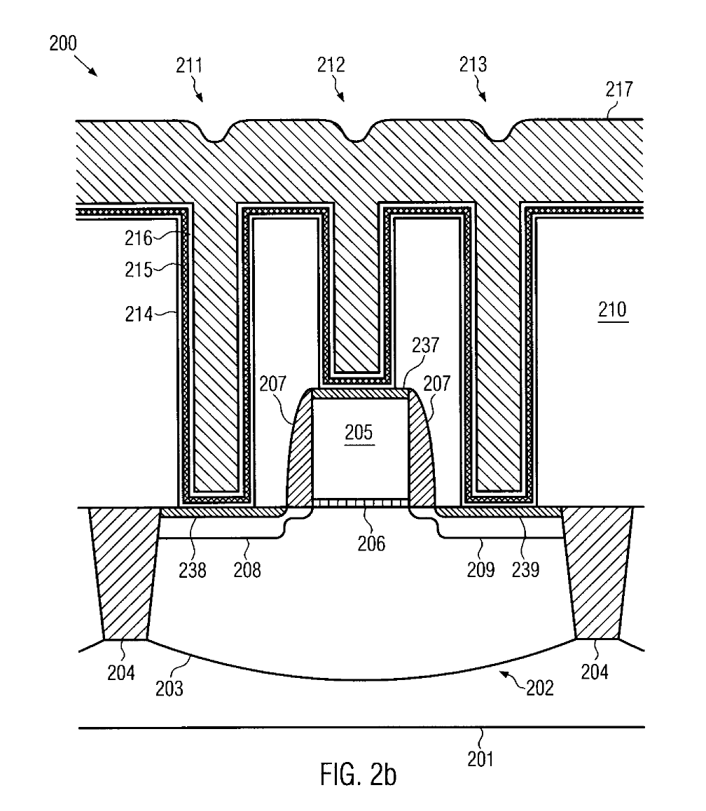

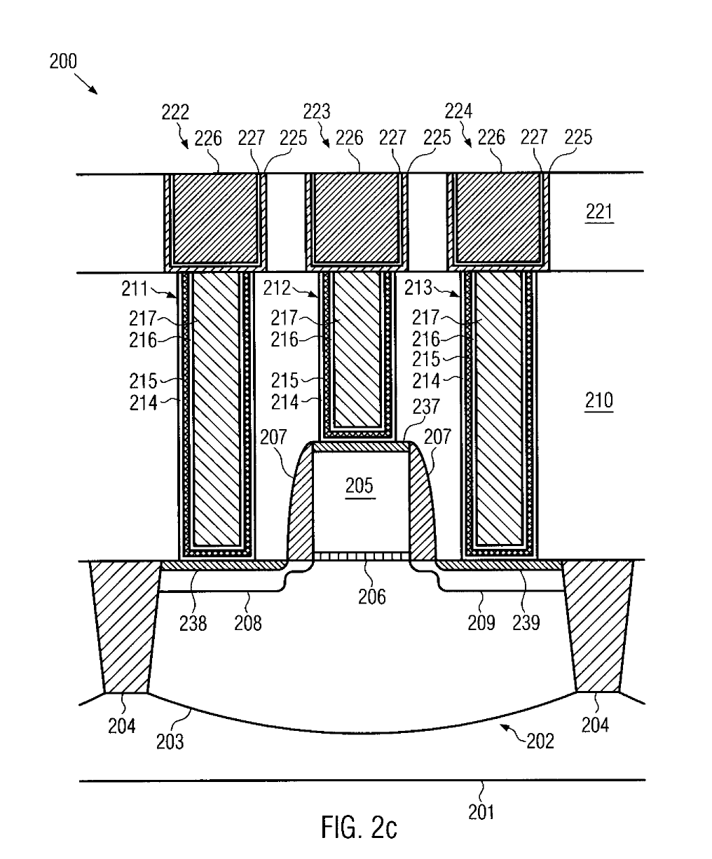

FIG. 2a shows a schematic cross-sectional view of a semiconductor structure 200 in a stage of an illustrative method of forming a semiconductor structure. The semiconductor structure 200 comprises a semiconductor substrate 201 which may, in some embodiments, comprise silicon. The substrate 201 may comprise a circuit element provided in the form of a field effect transistor 202. The field effect transistor 202 comprises an active region 203 formed in the substrate 201. A trench isolation structure 204 provides electric insulation between the field effect transistor 202 and other circuit elements in the semiconductor structure 200. The field effect transistor 200 further comprises a gate electrode 205 separated from the active region 203 by a gate insulation layer 206 and flanked by a sidewall spacer structure 207. Adjacent the gate electrode 205, a source region 208 and a drain region 209 may be provided. In some embodiments, a metal silicide region 238 may be formed in the source region 208. Further, metal silicide regions 237, 239 may be formed in the gate electrode 205 and in the drain region 209. The metal silicide regions 237, 238, 239 may, in some embodiments, comprise a nickel silicide. The metal silicide regions 237, 238, 239 may improve an electric conductivity of the source region 208, the drain region 209 and the gate electrode 205, which may help improve the performance of the field effect transistor 202.

The field effect transistor 202 may be formed by means of methods of photolithography, etching, oxidation, ion implantation, deposition and annealing well known to persons skilled in the art. In particular, the metal silicide regions 237, 238, 239 may be formed by depositing a layer of a refractory metal, for example, a layer comprising nickel, over the semiconductor structure 200 and then performing an annealing process to initiate a chemical reaction between the refractory metal and the silicon of the substrate 201.

A first layer 210 of a dielectric material is formed over the semiconductor structure 200. In some embodiments, the layer 210 may comprise silicon dioxide, silicon nitride and/or silicon oxynitride. In the formation of the layer 210, known deposition processes such as chemical vapor deposition and/or plasma enhanced chemical vapor deposition may be employed. The layer 210 may have a thickness which is greater than a height of the gate electrode 205 and may comprise a substantially planar surface.

A substantially planar surface of the layer 210 may be obtained by performing a planarization process after the deposition process. In some embodiments, a chemical mechanical polishing process may be used to planarize the layer 210 of dielectric material.

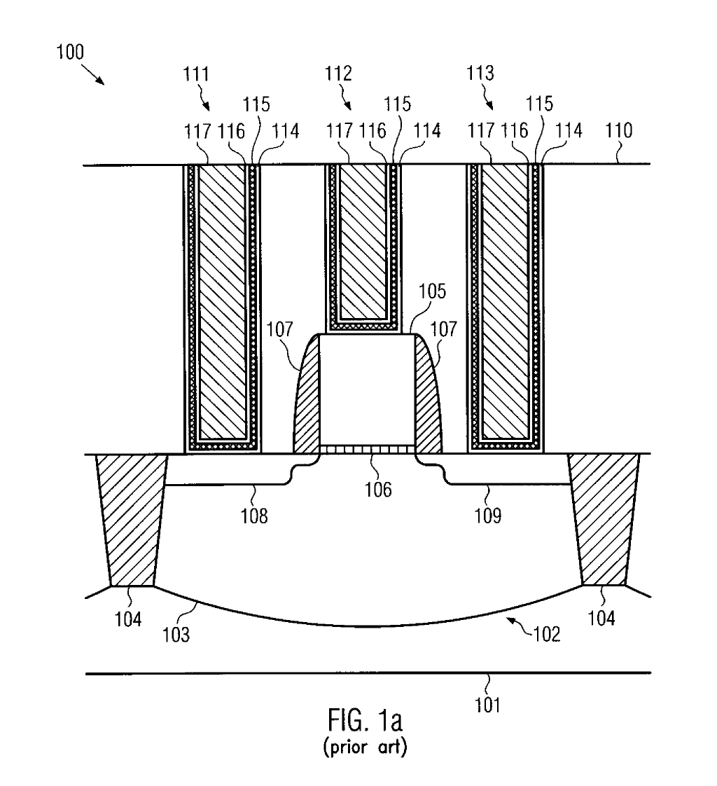

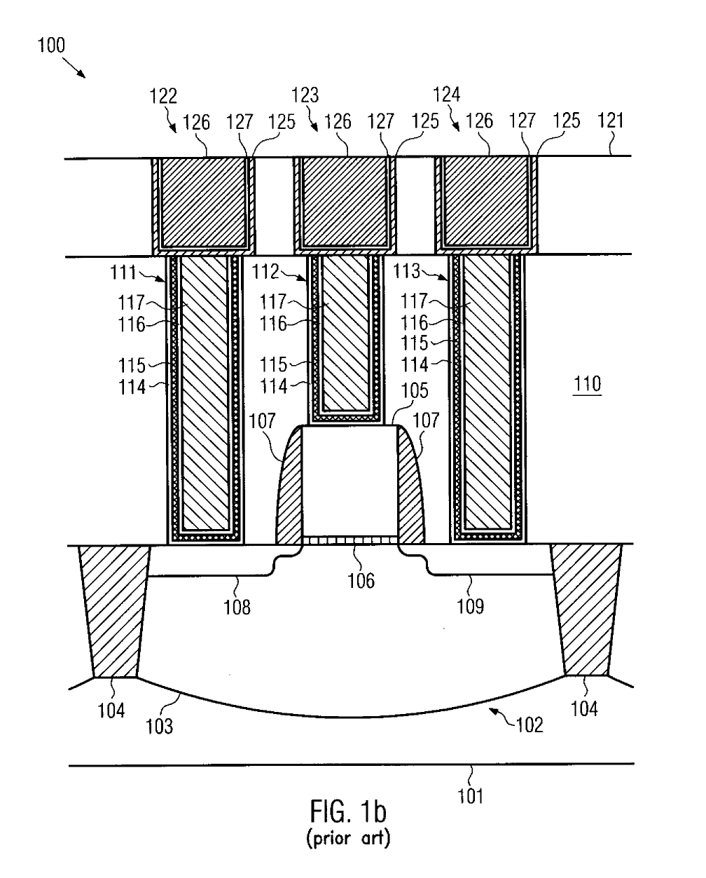

A first contact via 211 provided over the source region 208 of the field effect transistor 202, a second contact via 212 provided over the gate electrode 205 of the field effect transistor 202 and a third contact via 213 provided over the drain region 209 of the field effect transistor 202 may be formed in the layer 210 of dielectric material. Similar to the contact vias 111, 112, 113 in the manufacturing process according to the state of the art described above with reference to FIGS. 1a-1b, the contact vias 211, 212, 213 may be formed by photolithographically forming a mask (not shown) over the semiconductor structure 200, wherein the mask covers the layer 210 of dielectric material with the exception of those portions wherein the contact vias 211, 212, 213 are to be formed.

Thereafter, an anisotropic etching process adapted to selectively remove the material of the layer 210, leaving the material of the silicide regions 237, 238, 239 substantially intact, may be performed. In other embodiments, an etch stop layer comprising a material which is substantially not affected by an etchant used in the anisotropic etching process may be provided below the layer 210 of dielectric material to stop the etching process as soon as the contact vias 211, 212, 213 have reached the source region 208, the gate electrode 205 and the drain region 209, respectively. After the formation of the contact vias 211, 212, 213, the mask may be removed by means of a known resist strip process.

A first glue layer 214 may be formed over the semiconductor structure 200. The first glue layer 214 may comprise titanium. While, in some embodiments, the first glue layer 214 may comprise substantially pure titanium, in other embodiments, the first glue layer 214 may comprise a titanium alloy, for example, an alloy of titanium and tantalum.

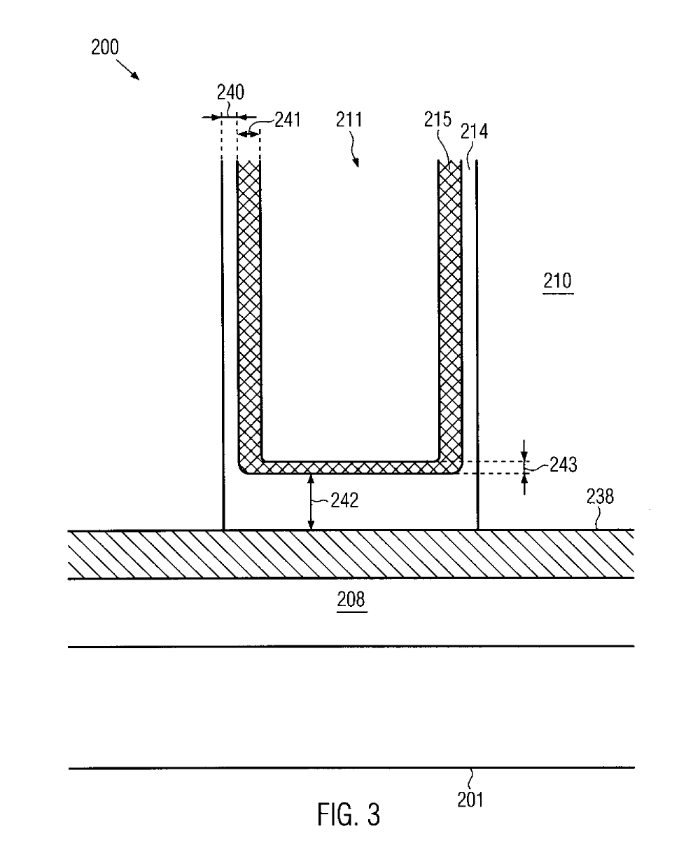

FIG. 3 shows a section of the semiconductor structure 200. In FIG. 3, the lower part of the contact via 211 formed over the metal silicide region 238 in the source region 208 of the field effect transistor 202 is shown. Reference numeral 240 denotes a thickness of portions of the first glue layer 214 on a sidewall of the contact via 211, and reference numeral 242 denotes a thickness of the first glue layer 214 on the bottom of the contact via 211. The thickness 242 of the first glue layer 214 on the bottom of the contact via 211 may be greater than the thickness 240 of the first glue layer 214 on the sidewall of the contact via 211. In the second contact via 212 and the third contact via 213, the first glue layer 214 may have a similar configuration as in the first contact via 211.

In some embodiments, the first glue layer 214 may be formed by means of plasma enhanced chemical vapor deposition. In plasma enhanced chemical vapor deposition, the semiconductor structure 200 may be provided in a reactor vessel. A reactant gas comprising at least one chemical compound comprising titanium is supplied to the reactor vessel. In the reactant gas, a high frequency glow discharge is created by applying a radio frequency alternating voltage to a pair of electrodes provided in the reactant gas, or by inductively coupling the radio frequency alternating voltage to the reactant gas. In addition to the radio frequency alternating voltage, a bias voltage may be applied between the semiconductor structure 200 and an electrode provided in the reactor vessel. On the surface of the semiconductor structure 200, or in the vicinity thereof, a chemical reaction is occurring in the reactant gas. In the chemical reaction, the material comprising titanium is formed. The material is then deposited on the surface of the semiconductor structure 200 to form the first glue layer 214.

Properties of the first glue layer 214 may be controlled by varying parameters of the plasma enhanced chemical vapor deposition process, such as, for example, temperature, pressure, flow and composition of the reactant gas, as well as frequency and/or amplitude of the radio frequency alternating voltage and the bias voltage. In particular, a degree of anisotropy of the plasma enhanced chemical vapor deposition process may be controlled by varying the bias voltage, wherein a greater bias voltage may lead to a higher degree of anisotropy.

In anisotropic deposition, a rate of deposition of the material of the first glue layer 214 depends on the orientation of the surface on which the first glue layer 214 is formed. In particular, a rate of deposition on substantially horizontal portions of the semiconductor structure 200 may be greater than a rate of deposition on inclined portions of the semiconductor structure 200. Thus, the thickness 242 of the first glue layer 214 on the bottom of the contact vias 211, 212, 213 may be greater than the thickness 240 of the first glue layer 214 on the sidewalls of the contact vias 211, 212, 213.

The present invention is not restricted to embodiments wherein the first glue layer 214 is formed by means of plasma enhanced chemical vapor deposition. In other embodiments, the first glue layer 214 may be formed by means of an ionized metal plasma deposition process. Ionized metal plasma deposition is a variant of physical vapor deposition wherein metal atoms which may, for example, be created by sputtering a target comprising the metal to be deposited (in embodiments disclosed herein, titanium and, optionally, tantalum) are ionized in a plasma. The plasma may be created by means of an electric glow discharge in a carrier gas which may, for example, comprise nitrogen and/or a noble gas. The electric glow discharge can be created by inductively coupling a radio frequency alternating voltage to the carrier gas and/or by applying the radio frequency alternating voltage to electrodes provided in the carrier gas. The ionized metal atoms are then accelerated towards the semiconductor structure 200 by means of a bias voltage applied between the substrate 201 and an electrode provided in a reactor vessel wherein the ionized metal plasma deposition process is performed. A degree of anisotropy of the ionized metal plasma deposition process may be controlled by varying the bias voltage.

In further embodiments, the first glue layer 214 may be formed by means of sputter deposition. In sputter deposition, a target comprising the material to be deposited is provided. In embodiments wherein the first glue layer 214 comprises substantially pure titanium, a titanium target may be used. In embodiments wherein the first glue layer 214 comprises a titanium alloy, a target comprising the titanium alloy may be used. In one embodiment, a target comprising an alloy of titanium and tantalum is provided.

The target is irradiated with ions, for example, ions of a noble gas, such as argon. Ions impinging on the target may knock atoms and/or molecules of the target material out of the target. The atoms and/or molecules may then impinge on the surface of the semiconductor structure 200 to form the first glue layer 214. In sputtering, the atoms and/or molecules may impinge on the semiconductor structure 200 from a direction of incidence depending on the relative orientation of the semiconductor structure 200 and the target. In particular, the target may be provided opposite the semiconductor structure 200 such that the atoms and/or molecules impinge on the semiconductor structure 200 from a direction of incidence being substantially perpendicular to the surface of the substrate 200. Thus, a higher density of atoms and/or molecules may impinge on the bottom surfaces of the contact vias 211, 212, 213 than on the sidewalls of the contact vias 211, 212, 213. This may lead to an anisotropy of the sputter deposition process such that the thickness 242 of the first glue layer 214 on the bottom of the contact vias 211, 212, 213 is greater than the thickness 240 of the first glue layer 214 on the sidewalls of the contact vias 211, 212, 213.

The present invention is not restricted to embodiments wherein the thickness 240 of the first glue layer on the bottom surface of the contact vias 211, 212, 213 and the thickness 242 of the first glue layer on the sidewalls of the contact vias 211, 212, 213 are different from each other. In other embodiments, the first glue layer 214 may be formed by means of a substantially conformal deposition process to obtain a substantially equal thickness of the first glue layer 214 on the bottom and on the sidewalls of the contact vias 211, 212, 213. Substantially conformal deposition of the first glue layer 214 may be obtained by means of a plasma enhanced chemical vapor deposition process wherein a low bias voltage or substantially no bias voltage is applied.

After the formation of the first glue layer 214, a second glue layer 215 may be formed over the semiconductor structure 200 and, in particular, over the contact vias 211, 212, 213. The second glue layer 215 may comprise tungsten nitride. In some embodiments, a thickness 241 (FIG. 3) of the second glue layer 215 on sidewalls of the contact vias 211, 212, 213 may be greater than a thickness 243 of the second glue layer 215 on bottom surfaces of the contact vias 211, 212, 213.

In some embodiments, the second glue layer 215 may be formed by means of atomic layer deposition. In atomic layer deposition, the semiconductor structure 200 is sequentially exposed to a plurality of gaseous precursor compounds which are sequentially flown to a reactor vessel wherein the semiconductor structure 200 is provided. While a first precursor is flown to the semiconductor structure 200, a substantially monoatomic layer of the first precursor may be formed over the first glue layer 214. An adhesion between molecules of the first precursor may be weak. Therefore, a deposition of more than one monoatomic layer of the first precursor may be substantially avoided by adapting the temperature of the atomic layer deposition process. Thereafter, a second precursor is flown to the semiconductor structure 200. The second precursor reacts chemically with the first precursor present on the surface of the semiconductor structure 200. In the chemical reaction, tungsten nitride may be created. In one embodiment, tungsten hexafluoride (WF₆) and ammonia (NH₃) may be used as the first precursor and the second precursor, respectively. In another embodiment, bis(tert-butylimido)bis(dimethylamido)tungsten and ammonia may be used as the first and the second precursor, respectively.

In other embodiments, the second glue layer 215 may be formed by means of reactive ion sputtering. In reactive ion sputtering, a target comprising tungsten may be irradiated with energetic ions to create tungsten atoms and/or ions which are ejected out of the target. The tungsten atoms and/or ions may react chemically with nitrogen or a chemical compound comprising nitrogen such as ammonia provided in a reaction chamber wherein the reactive ion sputtering is performed to create tungsten nitride which is then deposited on the surface of the semiconductor structure 200. The energetic ions used for sputtering the target comprising tungsten may be created by means of a radio frequency glow discharge created in the reaction chamber which may, in addition to nitrogen and/or a chemical compound comprising nitrogen, comprise a noble gas such as, for example, argon (Ar). In some embodiments, the reactive ion sputtering may comprise magnetron sputtering wherein a magnetic field is created in the vicinity of the target to confine plasma created by the radio frequency glow discharge in the vicinity of the target.

After the creation of the second glue layer 215, the second glue layer 215 may be modified by reducing the thickness 243 of the second glue layer 215 on the bottom surfaces of the contact vias 211, 212, 213 and/or by increasing the thickness 241 of the second glue layer 215 on the sidewalls of the contact vias 211, 212, 213.

In some embodiments, a sputtering process may be employed for this purpose. In the sputtering process, the semiconductor structure 200 may be irradiated with ions impinging on the semiconductor structure 200 from a direction being substantially perpendicular to the surface of the substrate 201. Thus, ions may fly through the contact vias 211, 212, 213 and may impinge on the bottom surfaces of the contact vias 211, 212, 213. The ions may knock atoms and/or molecules out of portions of the second glue layer 215 located over the bottom surfaces of the contact vias 211, 212, 213 such that the thickness 243 of the second glue layer 215 over the bottom surfaces of the contact vias 211, 212, 213 is reduced.

The direction of incidence of the ions may be substantially parallel to the sidewalls of the contact vias 211, 212, 213. Thus, only a small amount of material, or substantially no material at all, may be removed from the sidewalls of the contact vias 211, 212, 213 during the sputtering process. Hence, a reduction of the thickness of the second glue layer 215 over the sidewalls of the contact vias 211, 212, 213 may be substantially avoided. In some embodiments, the thickness 241 of the second glue layer 215 may be increased during the sputtering process, since atoms and/or molecules sputtered away from the bottom surfaces of the contact vias 211, 212, 213 may be deposited on the sidewalls of the contact vias 211, 212, 213.

Advantageously, reducing the thickness of the second glue layer 215 at the bottom of the contact vias 211, 212, 213 may help reduce an electrical resistivity of an interface between electrical connections formed in the contact vias 211, 212, 213 and the source region 208, the gate electrode 205 and the drain region 209 of the field effect transistor 202.

The present invention, however, is not restricted to embodiments wherein the thickness 243 of the second glue layer 215 over the bottom surfaces of the contact vias 211, 212, 213 is smaller than the thickness 241 of the second glue layer 215 over the sidewalls of the contact vias 211, 212, 213. In other embodiments, the thickness 243 may be substantially equal to the thickness 241, or may even be greater than the thickness 241.

FIG. 2b shows a schematic cross-sectional view of the semiconductor structure 200 in a later stage of the manufacturing process. After the formation of the first glue layer 214 and the second glue layer 215, a seed layer 216 comprising tungsten may be formed over the second glue layer 215. Similar to the seed layer 116 in the semiconductor structure 100 according to the state of the art described above with reference to FIGS. 1a-1b, the seed layer 216 may be formed by means of an atomic layer deposition process. Compared to the titanium nitride layer 115 provided in the semiconductor structure 100 according to the state of the art, the second glue layer 215 comprising tungsten nitride may improve a nucleation of the seed layer 216. Hence, the seed layer 216 may have a greater degree of homogeneity than the seed layer 116 in the semiconductor structure 100 according to the state of the art, and a formation of holes in the seed layer 216 may be reduced or substantially avoided.

On the seed layer 216, a layer 217 comprising tungsten may be formed by means of known processes of chemical vapor deposition and/or plasma enhanced chemical vapor deposition to fill the contact vias 211, 212, 213 with material comprising tungsten.

FIG. 2c shows a schematic cross-sectional view of the semiconductor structure 200 in a later stage of the manufacturing process. After the formation of the layer 217 comprising tungsten, a planarization process, for example a chemical mechanical polishing process, may be performed. In the chemical mechanical polishing process, the semiconductor structure 200 may be moved relative to a polishing pad. A slurry comprising compounds adapted to react chemically with materials on the surface of the semiconductor structure 200, in particular with the material comprising tungsten of the layer 217, is supplied to an interface between the semiconductor structure 200 and the polishing pad. Reaction products are removed by abrasives in the slurry and/or the polishing pad. In the chemical mechanical polishing process, portions of the layer 217 outside the contact vias 211, 212, 213 may be removed and a substantially planar surface of the semiconductor structure 200 may be obtained.

In the chemical mechanical polishing process, friction between the semiconductor structure 200 and the polishing pad may create mechanical forces in the semiconductor structure 200. The first glue layer 214 may increase an adhesion between the second glue layer 215 and other portions of the semiconductor structure 200. In particular, an adhesion between the second glue layer 215 and the metal silicide regions 237, 238, 239 may be improved. Thus, mechanical damages of the semiconductor structure 200 caused by the chemical mechanical polishing process may be reduced, or may be substantially avoided.

After the chemical mechanical polishing process, a second layer 221 of a dielectric material, which may comprise silicon dioxide, silicon nitride and/or silicon oxynitride, or a low-k material such as hydrogen silsesquioxane, may be formed over the semiconductor structure 200 by means of a known deposition process, such as spin coating, chemical vapor deposition and/or plasma enhanced chemical vapor deposition.

In the second layer 221 of dielectric material, trenches 222, 223, 224 may be formed, wherein the trench 222 may be formed over the first contact via 211, the trench 223 may be formed over the second contact via 212 and the trench 224 may be formed over the third contact via 213. Thereafter, a diffusion barrier layer 225 which may comprise a material adapted to substantially prevent a diffusion of copper through the diffusion barrier layer 225 may be deposited over the semiconductor structure 200 by means of a deposition process known to persons skilled in the art.

After the formation of the diffusion barrier layer 225, a seed layer 227, which may, in some embodiments, comprise copper, may be deposited by means of a known process of sputtering, chemical vapor deposition and/or plasma enhanced chemical vapor deposition, and a known electroplating process may be performed to deposit a layer 226 of a material comprising copper over the semiconductor structure 200. In particular, the trenches 222, 223, 224 may be filled with the material comprising copper. Thereafter, a chemical mechanical polishing process may be performed to remove portions of the diffusion barrier layer 225, the seed layer 227 and the layer 226 of the material comprising copper which were deposited outside the trenches 222, 223, 224.

Thus, in the trenches 222, 223, 224, electrically conductive lines comprising copper may be formed. The contact vias 211, 212, 213 provide electrical connections between the electrically conductive lines in the trenches 222, 223, 224 and the source region 208, the gate electrode 205 and the drain region 209 of the field effect transistor 202, respectively.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor structure, comprising:
providing a semiconductor substrate comprising a layer of a dielectric material having a recess therein;
forming a first glue layer and a second glue layer in said recess, said first glue layer comprising titanium, said second glue layer comprising tungsten nitride; and
filling said recess with a material comprising tungsten.

2. The method of forming a semiconductor structure as in claim 1, wherein said second glue layer is formed over said first glue layer.

3. The method of forming a semiconductor structure as in claim 1, wherein a thickness of said second glue layer over a sidewall of said recess is greater than a thickness of said second glue layer over a bottom surface of said recess.

4. The method of forming a semiconductor structure as in claim 3, wherein a sputtering process is performed to reduce a thickness of said second glue layer over said bottom surface of said recess.

5. The method of forming a semiconductor structure as in claim 1, wherein said recess comprises a contact via.

6. The method of forming a semiconductor structure as in claim 5, wherein said semiconductor substrate comprises a metal silicide region provided at a bottom of said contact via.

7. The method of forming a semiconductor structure as in claim 6, wherein said metal silicide comprises a nickel silicide.

8. The method of forming a semiconductor structure as in claim 1, wherein filling said recess with said material comprising tungsten comprises:
depositing a layer of said material comprising tungsten over said semiconductor substrate; and
performing a planarization process to remove portions of said layer of said material comprising tungsten outside said recess.

9. A method of forming a semiconductor structure, comprising:
providing a semiconductor substrate comprising a field effect transistor, said field effect transistor comprising a source region and a drain region, said source region and said drain region comprising a metal silicide;
forming a layer of a dielectric material over said field effect transistor;
forming a first contact via and a second contact via in said layer of dielectric material, said first contact via being provided over said source region, said second contact via being provided over said drain region;
forming a first glue layer comprising titanium over a bottom surface of said first contact via and a bottom surface of said second contact via;
forming a second glue layer comprising tungsten nitride over said first contact via and said second contact via; and
filling said first contact via and said second contact via with a material comprising tungsten.

10. The method of forming a semiconductor structure as in claim 9, wherein said second glue layer is formed over said first glue layer.

11. The method of forming a semiconductor structure as in claim 9, wherein a thickness of said second glue layer over sidewalls of said first contact via and said second contact via is greater than a thickness of said second glue layer over said bottom surface of said first contact via and said bottom surface of said second contact via.

12. The method of forming a semiconductor structure as in claim 11, wherein a sputtering process is performed to reduce a thickness of said second glue layer over said bottom surface of said first contact via and said bottom surface of said second contact via.

13. The method of forming a semiconductor structure as in claim 9, wherein said formation of said first glue layer comprises performing an anisotropic deposition process.

14. The method of forming a semiconductor structure as in claim 19, wherein said metal silicide comprises a nickel silicide.

15. A semiconductor structure, comprising:
a semiconductor substrate comprising a layer of a dielectric material;
a recess provided in said layer of dielectric material; and
a first glue layer and a second glue layer formed over said recess, said first glue layer comprising titanium, said second glue layer comprising tungsten nitride;
wherein said recess is filled with a material comprising tungsten.

16. The semiconductor structure as in claim 15, wherein said second glue layer is formed over said first glue layer.

17. The semiconductor structure as in claim 15, wherein a thickness of said second glue layer over a sidewall of said recess is greater than a thickness of said second glue layer over a bottom surface of said recess.

18. The semiconductor structure as in claim 15, wherein a thickness of said first glue layer over a bottom surface of said recess is greater than a thickness of said first glue layer over a sidewall of said recess.

19. The semiconductor structure as in claim 15, wherein said recess comprises a contact via and wherein said semiconductor substrate comprises a metal silicide region provided at a bottom of said contact via.

20. The semiconductor structure as in claim 19, wherein said metal silicide comprises a nickel silicide.
